(19) United States
(12) Patent Application Publication
(10) Pub. No.: US 2006/0195774 A1
(43) Pub. Date: Aug. 31, 2006

(54) Error correction circuit and method

(76) Inventors: Stephen Bowyer, Raleigh, NC (US); Alan Daniel, Durham, NC (US)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 11/059,899

(22) Filed: Feb. 17, 2005

(51) Int. Cl. G06F 11/00; H03M 13/00

(52) U.S. Cl. 714/800

(57) ABSTRACT

The present invention includes an error correction circuit with a data memory, a write tree, a parity memory, and a read tree. The data memory is configured to hold a set of data. The write tree is configured to receive the set of data and to generate parity data. The parity memory is coupled to the write tree and is configured to receive and hold parity data. The read tree is configured to receive data from the data memory and parity data from the parity memory. The read tree is configured to generate an indication of whether an error has occurred in the data during storage within the data memory.

### BACKGROUND

The present invention relates to an error correction circuit and method. In particular, a system and method are provided for an error correction circuit used in association with a dynamic random access memory (DRAM) system. More recently, manufacturers and customers are increasingly using “known good die” (KGD) applications. With KGD applications, customers are provided with wafers of devices instead of individually packaged components. The customer then accomplishes the packaging step. For example, DRAM may be delivered to a customer as a KGD, and then the customer combines the KGD with other devices into the same package.

In the packaging process, however, it is possible to introduce single cell failures in the DRAM of the KGD. In some cases, introduction of such failures can result in the need to scrap the entire package afterwards. In many cases, because the KGD is being packaged with a significantly expensive device, scrapping the entire package is a very expensive loss to the customers. Moreover, even where failures are not introduced in the packaging of the various devices, it is still increasingly difficult to deliver current high-density DRAM memories as KGD to customers without single-cell defects. Consequently, a solution is needed to recover the DRAM cells after packaging.

For these and other reasons, there is a need for the present invention.

### SUMMARY

One aspect of the present invention provides an error correction circuit including a data memory, a write tree, a parity memory, and a read tree. The data memory is configured to hold a set of data. The write tree is configured to receive the set of data and to generate parity data. The parity memory is coupled to the write tree and is configured to receive and hold parity data. The read tree is configured to receive data from the data memory and parity data from the parity memory. The read tree is configured to generate an indication of whether an error has occurred in the data during storage within the data memory.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated, as they become better understood by reference to the following detailed description. The elements of the drawings are not necessarily to scale relative to each other. Like reference numerals designate corresponding similar parts.

FIG. 1 illustrates a block diagram of a known good die having a memory and error correction circuitry.

FIG. 2 is a table illustrating an error correction code.

FIG. 3 is a table illustrating a modified correction code in accordance with one embodiment of the present invention.

FIG. 4 illustrates a data memory and an error correction circuit in accordance with one embodiment of the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

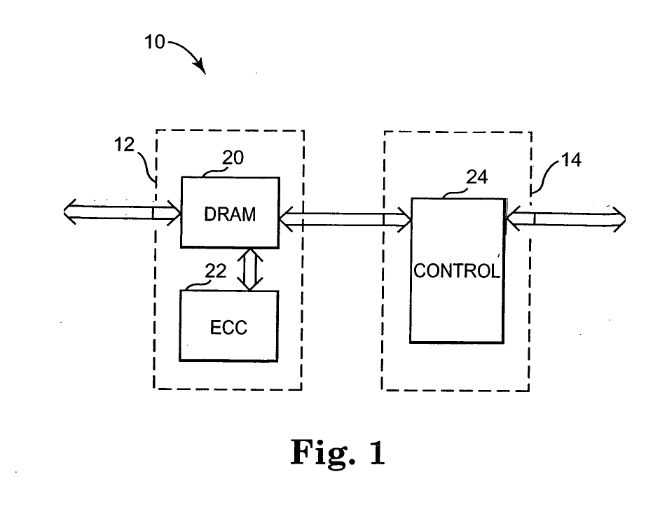

FIG. 1 illustrates a block diagram of application package 10 in accordance with one embodiment of the present invention. Application package 10 includes known good die (KGD) 12 and application die 14. In one case, KGD 12 includes dynamic random access memory (DRAM) 20, which includes a large number of single cells that may be used to store bits of data. KGD 12 further includes error correction circuit 22, as will be discussed more fully below. Application die 14, in one case, may include control circuit 24, which may be a microcontroller or similar device. In other embodiments, application die 14 may not include control circuit 24, and may instead include another DRAM die or dies, flash memory die(s), another type of memory die(s), a microprocessor, or a microcontroller that controls the DRAM KGD. The functionality of application die 14 is not particularly important to ECC 20.

KGD 12 and application die 14 may be packaged together as application package 10 for use in a variety of applications that utilize memory. In one embodiment, DRAM 20 can be accessed by application die 14, or components therein, or can be accessed by external components. In one embodiment where application die 14 includes control circuit 24, control circuit 24 can access DRAM 20 and may be coupled to additional external components.

Typically, its manufacturer delivers KGD 12 to a customer, who may then package KGD 12 with application die 14 into application package 10. In cases where single cell failures are introduced into DRAM 20 that is within KGD 12, either during its packaging or even in cases where the failures occurred before or after packaging, error correction circuit 22 may be used to correct these failures in accordance with one embodiment of the present invention.

Error correction of cells or bits may be accomplished be employing an error correction code. One such known code is the Hamming code. Essentially, the Hamming code can detect and correct bit errors by inserting error correction or parity bits into a data stream, thereby increasing the overall number of bits. In one case, a Hamming code may be a (15,11). In such a case, an 11-bit data stream has four parity bits inserted to bring the total number of bits to 15. The parity bits may be examined after data is extracted to determine whether a bit error has occurred.

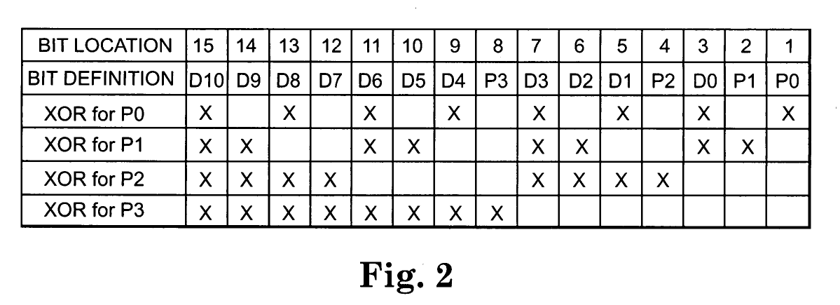

FIG. 2 is a table illustrating a (15,11) Hamming code. The first row in the table lists the bit locations 1-15. As indicated, after insertion of the four parity bits, there are 15 total bit locations. The second row in the table lists the bit definitions. Data bits from the 11-bit data stream are indicated with D0, D1, D2, D3, D4, D5, D6, D7, D8, D9, and D10. The four parity bits are indicated with P0, P1, P2, and P3. As may be apparent, the parity bits are located in each of the locations that are powers of 2, or at locations 2ⁿ, such that they will be in positions 1, 2, 4, and 8.

Each parity bit then calculates the parity for some of the bits in the code word. The position of the parity bit determines the sequence of bits that it alternatively checks and skips. For P0 in the first position, the sequence of bits will be to check every other one bit location, that is, check one, skip one, check one skip one, etc. For P1 in the second position, the sequence of bits will be to check every other two bit locations, that is, check two, skip two, check two skip two, etc. For P2 in the third position, the sequence of bits will be to check every other four bit locations, that is, check four, skip four, check four skip four, etc. For P3 in the fourth position, the sequence of bits will be to check every other eight bit locations, that is, check eight, skip eight, check eight skip eight, etc.

For a write operation, the parity bit is then set to 1 if the total number of ones in the sequence of positions is odd and will be set to 0 is the total number of ones in the sequence of positions is even. This may be accomplished by performing an exclusive or (“XOR”) logic operation on the data bits in the sequence associated with each parity bit (excluding the parity bit from the XOR operation). The result of the XOR operation determines the value of the associated parity bit. In this way, if D0=1, D1=1, D3=0, D4=0, D6=1, D8=1, and D10=0, then P0 is set to 1.

Then, for a read operation, a XOR operation of the data bits along with the associated parity bit determines whether there is bit failure. If the result of the XOR operation is zero, then there was no bit failure. Where the result is not zero, however, it indicates a failure or error in the bit position associated with the parity bit. For example, if the XOR operation including the parity bit returns a result 0011, this indicates that there is a bit failure in bit 3, which is D0.

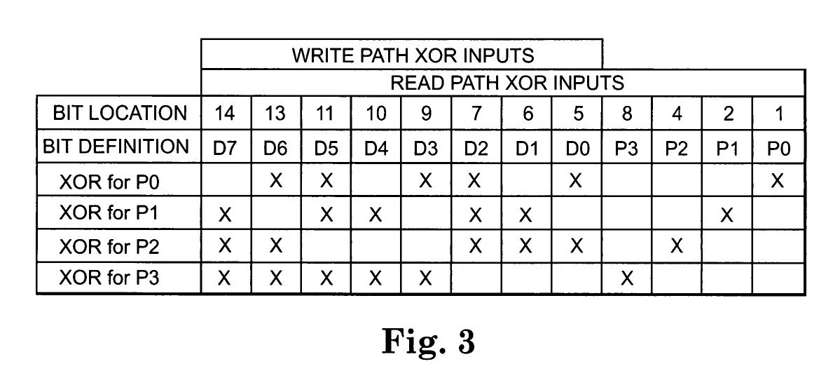

FIG. 3 is a table illustrating a modified correction code in accordance with one embodiment of the present invention. The illustrated may be referred to as a (12,8) error code. With this modified code, the principal rules are the same as described above for the illustrated (15,11) code in FIG. 3, only eight data bits are used and three of the data bits from are thrown away. In one embodiment, the discarded bits are selected such that a more balanced code is achieved.

For example, in one embodiment bit locations 3, 12, and 15 may be discarded. Since bit location 15 appears in each parity bit sequence P0-P3, its discard maintains balance. Similarly, since bit location 3 appears in half of the parity bit sequences P0-P3, and bit location 12 in the other half, the combined discard also maintains balance. One skilled in the art will see that other discard combinations may also be achieved while maintaining balance.

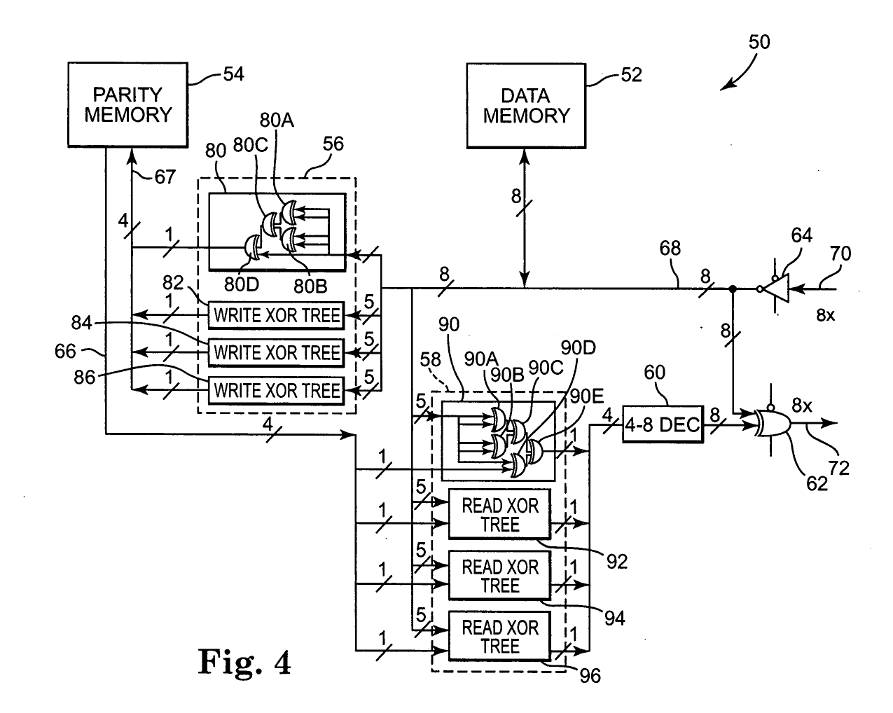

In FIG. 3, the bit locations have been reorganized to place the parity bits at the far right. The first row in the table lists the bit locations 1-2, 4-11 and 12-14 (bit locations 3, 12 and 15 having been discarded). The second row in the table lists the bit definitions. The four parity bits are indicated with P0, P1, P2, and P3 on the far right side. Again, the parity bits are located in each of the locations that are powers of 2, or at locations 2ⁿ, such that they will be in positions 1, 2, 4, and 8. Data bits from the 8-bit data stream are indicated with D0, D1, D2, D3, D4, D5, D6, and D7. As will be more evident in the explanation below with respect to FIG. 4, the modified error correction code illustrated in FIG. 3 has advantages in embodiments of certain configuration.

As with the error correction code illustrated in FIG. 2, the modified correction code illustrated in FIG. 3 is such that each parity bit calculates the parity for some of the bits in the code word. The position of the parity bit determines the sequence of bits that it alternatively checks and skips. For P0 in the first position, the sequence of bits will be to check every other one bit location, that is, check one, skip one, check one skip one, etc. This sequence is determined before bit locations 3, 12 and 15 are discarded such that these later-discarded bits are still checked or skipped when determining the sequence for each parity bit. For P1 in the second position, the sequence of bits will be to check every other two bit locations, that is, check two, skip two, check two skip two, etc. For P2 in the third position, the sequence of bits will be to check every other four bit locations, that is, check four, skip four, check four skip four, etc. For P3 in the fourth position, the sequence of bits will be to check every other eight bit locations, that is, check eight, skip eight, check eight skip eight, etc.

For a write operation, the parity bit is then set 1 if the total number of ones in the sequence of positions is odd and will be set to 0 is the total number of ones in the sequence of positions is even. This may be accomplished by performing a XOR logic operation on the data bits in the sequence associated with each parity bit (excluding the parity bit from the XOR operation). The result of the XOR operation determines the value of the associated parity bit.

FIG. 4 illustrates a data memory and an error correction circuit (“ECC”) 50 in accordance with one embodiment of the present invention. In one embodiment, it may be used in association with the modified error correction code illustrated in FIG. 3. ECC 50 includes data memory 52, parity memory 54, write tree 56, read tree 58, decoder 60, read data buffer 62, and write data buffer 64. In operation, ECC 50 utilizes parity data in writing and reading data to determine whether bit failures or errors occur in the data during storage within data memory 52, to identify the particular bits that were affected by any such error, and/or to correct any such error.

Data memory 52 may be DRAM, or a portion thereof, such as DRAM 20 illustrated in FIG. 1. Data memory 52 stores normal read/write data, which is written to or read from DRAM by an external user. Normal read/write data is interfaced with data memory 52 via read/write line 68, which is coupled to read and write buffers 62 and 64. With EEC 50, error detection and correction logic is integrated into the data path of the device, as will be explained more fully below.

Parity memory 54 is used to store parity data that is generated from the normal write data. During a write operation, normal write data is received from write buffer 64 by write tree 56 such that write parity data is generated and sent on write parity line 67 to parity memory 54. In one embodiment, write tree 56 includes first, second, third and fourth write tree segments 80, 82, 84, and 86. During a read operation, the parity data is read out of parity memory 54 in parallel with the normal data out of data memory 52. Read parity data is received by read tree 58 via read parity data line 66 from parity memory 54. In one embodiment, read tree 58 includes first, second, third and fourth read tree segments 90, 92, 94, and 96. The output from read tree 58 is received by decoder 60 and sent to read data buffer 62.

In operation of one embodiment of ECC 50, normal write data 70 is received from an external source at write buffer 64. In one embodiment, the normal write data is eight bits of data. Normal write data is then sent in parallel to data memory 52 via read/write line 68 and to write tree 56. Write tree 56 then generates parity data associated with the eight bits of normal write data.

In one embodiment, write tree 56 uses first, second, third and fourth write tree segments 80, 82, 84, and 86 to generate the parity data. Each of the four write tree segments 80-86 receive a combination of five bits of the eight bits of normal write data. In one embodiment, the combination of five bits is determined in accordance with the modified correction code illustrated in FIG. 3. Write path XOR inputs are designated in the illustration. In this way, each one of the four write tree segments 80-86 is associated with one parity bit. For example, in one embodiment first write tree segment 80 is associated with parity bit P0, second write tree segment 82 is associated with parity bit P1, third write tree segment 84 is associated with parity bit P2, and fourth write tree segment 86 is associated with parity bit P3.

Thus, in one embodiment, first write tree segment 80 receives five bits from the normal write data bits. In one case, those bit locations are the ones that have an “X” designated in the row labeled “XOR for P0” in FIG. 3. In this way, the five selected bits come from checking every other one bit location, that is, check one, skip one, check one skip one, etc. These five bits are sent to XOR gates so that a single output bit will result. This resulting bit is the parity bit associated with that sequence, which in this case is P0.

Second write tree segment 82 similarly receives bits from those bit locations that have an “X” designated in the row labeled “XOR for P1” in FIG. 3. In this way, the five selected bits come from checking every other two bit locations, that is, check two, skip two, check two skip two, etc. These five bits are sent to XOR gates so that a single output bit will result. This resulting bit is the parity bit associated with that sequence, which in this case is P1.

Third write tree segment 84 similarly receives bits from those bit locations that have an “X” designated in the row labeled “XOR for P2” in FIG. 3. In this way, the five selected bits come from checking every other four bit locations, that is, check four, skip four, check four skip four, etc. These five bits are sent to XOR gates so that a single output bit will result. This resulting bit is the parity bit associated with that sequence, which in this case is P2.

Fourth write tree segment 86 similarly receives bits from those bit locations that have an “X” designated in the row labeled “XOR for P3” in FIG. 3. In this way, the five selected bits come from checking every other eight bit locations, that is, check eight, skip eight, check eight skip eight, etc. These five bits are sent to XOR gates so that a single output bit will result. This resulting bit is the parity bit associated with that sequence, which in this case is P3.

In one embodiment, each of write tree segments 80-86 includes five XOR gates that are in three stages. For example, in one embodiment, first write tree segment 80 includes five XOR gates 80A-80E. In a first stage, XOR gates 80A and 80B receive four of the five selected bits of normal write data. In a second stage XOR gate 80C receives the outputs from the gates in the first stage (XOR gates 80A and 80B). In a third and final stage XOR gate 80D then receives the output of XOR gate 80C from the second stage and receives the remaining fifth bit of normal write data. The output of XOR gate 80D of the third stage is the parity bit (for example, P0). For example, parity bit P0 is output from write tree segment 80, P1 is output from write tree segment 82, P2 is output from write tree segment 84, and P3 is output from write tree segment 86. The four parity bits P0-P3 are then stored in parity memory 54 via write parity line 67.

One skilled in the art will recognize that other configuration of logic gates and similar circuitry will accomplish similar results consistent with the present invention. Furthermore, each of the other write tree segments 82-86 can include five XOR gates that are in three stages similar to that illustrated with respect to write tree segment 80.

During the read operation, read tree 58 combines normal read data from data memory 52 with the corresponding parity read data from parity memory 54 to determine whether an error has occurred in the data during the storage operation. The output of read tree 58 indicates whether an error has occurred and which bit position contains the error.

In one embodiment, each of the parity data bits P0-P3 are input to one of read tree segments 90-96. For example, in one embodiment parity bit P0 is input to first read tree segment 90, parity bit P1 is input to second read tree 92, parity bit P2 is input to third read tree 94, and parity bit P3 is input to fourth read tree 96. In parallel, each of the four read tree segments 90-96 receive a combination of five bits of the eight bits of normal read data. In one embodiment, the combination of five bits is determined in accordance with the modified correction code illustrated in FIG. 3. Read path XOR inputs are designated in the illustration.

Thus, in one embodiment, first read tree segment 90 receives parity bit P0 and the five bits from the normal read data in the bit locations marked with an “X” in the row labeled “XOR for P0” (in FIG. 3). Similarly, second read tree segment 92 receives parity bit P1 and five of the bits from the normal read data in the bit locations marked with an “X” in the row labeled “XOR for P1” (in FIG. 3). Similarly, third read tree segment 94 receives parity bit P1 and five of the bits from the normal read data in the bit locations marked with an “X” in the row labeled “XOR for P2” (in FIG. 3). And finally, fourth read tree segment 96 similarly receives parity bit P3 and five of the bits from the normal read data in the bit locations marked with an “X” in the row labeled “XOR for P3” (in FIG. 3).

In one embodiment, each of the four read tree segments 90-96 include five XOR gates that are in three stages. For example, in one embodiment, first read tree segment 90 includes five XOR gates 90A-90E. In a first stage, XOR gates 90A and 90B receive four of the five selected bits of normal write data. In a second stage XOR gate 90C receives the outputs from the gates in the first stage and XOR gate 90D receives the remaining fifth bit of normal read data along with the parity bit. In a third and final stage XOR gate 90E then receives the output of both gates from the second stage (90C and 90D), and then outputs the result to decoder 60.

One skilled in the art will recognize that other configuration of logic gates and similar circuitry will accomplish similar results consistent with the present invention. Furthermore, each of the other read tree segments 92-96 can include five XOR gates that are in three stages similar to that illustrated with respect to first read tree segment 90.

In one embodiment, decoder 60 determines whether there was a bit failure in the data during the storing operation. In one embodiment, decoder 60 is a standard one-hot decoder that interprets the result of the read tree 58 and sets one output to active to indicate which data bit, if any, has an error. A read/write switch either passes each read data bit unchanged or inverts the bit, based on whether the given bit is the bit in error, on read out line 72.

In one embodiment, the result coming from the read tree segments 90-96 determine whether an error occurred and also identify the affected bit. For example, if the result out of read tree segments 90-96 is “0000”, then this means that there was not failure or error in the data during the storage time. On the other hand, if the result out of read tree segments 90-96 is “1010”, then this means that there was an error, and that the error occurred in bit location 10, which corresponds to D4 (See FIG. 3).

In one embodiment, the (12,8) modified correction code illustrated in FIG. 3 is integrated into the data path within EEC 50. In this way, there is no need for invasive changes to the memory array structure, while still providing the highest number of correctable errors on the device.

In one embodiment, data memory 52 is placed in close proximity to data read/write buffers 62 and 64 in order to provide relatively fast data timing. On the other hand, parity memory 54 is placed further from data read/write buffers 62 and 64 relative to data memory 52. This results in the slower timing of parity data relative to that of data memory 52. In one embodiment, this slower timing is compensated for in read tree 58.

In this way, in operation of one embodiment of ECC 50, the parity read data enters the second stage of read tree segments 90-96 (for example, XOR gate 90D), while the normal read data enters at the first stage (for example, XOR gates 90A and 90B). In this way, the timing differences between the fast normal data and relatively the slow parity data can be cancelled out and/or compensated for. Furthermore, because the modified code illustrated in FIG. 3 uses only five bits of read data for read tree 58, only three stages of logic gates are used in one embodiment. Thus, the timing differences between the fast normal data and relatively the slow parity data can be compensated for with the extra stage of logic gates. Where additional bits of read data are used, such as the seven bits illustrated for each parity bit in FIG. 2, compensating for timing differences would be more complicated.

In addition, providing separate write tree 56 and read tree 58 circuits for the write and read paths, allows for optimal placement of the read and trees 56 and 58 in order to achieve good overall timing in ECC 50. Write tree 56 is used to generate the parity data based on the values of the normal write data and the correction code. The output of the write tree 56 is written directly into the parity memory 54.

Although specific embodiments have been illustrated and described herein, it will be appreciated by those of ordinary skill in the art that a variety of alternate and/or equivalent implementations may be substituted for the specific embodiments shown and described without departing from the scope of the present invention. For example, FIG. 3 illustrates bit definitions for eight bits, or for a single byte of data. One skilled in the art will see how the present invention is also applicable to multiple bytes, as well as the illustrated single-byte example. Each additional byte of data will have its associated four parity bits and along with the selected five-bit sequence of data bits within the byte. In this way, 16-bit, 32-bit, and 64-bit, as well as other configurations, may be easily accommodated with ECC 50.

Thus, this application is intended to cover any adaptations or variations of the specific embodiments discussed herein. Therefore, it is intended that this invention be limited only by the claims and the equivalents thereof.

What is claimed is:

1. An error correction circuit comprising:
a data memory configured to receive and store a set of data;
a write tree configured to receive the set of data and to generate parity bits;
a parity memory coupled to the write tree configured to receive and hold parity bits; and
a read tree configured to receive the set of data from the data memory and parity bits from the parity memory and configured to generate an indication of failure within the data memory.

2. The error correction circuit of claim 1, wherein the write tree further comprises a first, a second, a third and a fourth write tree segment and wherein each write tree segment logically combines a subset of the set of data to produce the parity bits.

3. The error correction circuit of claim 1, wherein the read tree further comprises a first, a second, a third and a fourth write read segment and wherein each write tree segment logically combines a subset of the set of data from the data memory with one of the parity bits to determine whether a failure occurred within the set of data stored in the data memory.

4. The error correction circuit of claim 3, wherein the subset of data combined by each of the read tree segments is selected according to a modified Hamming code.

5. The error correction circuit of claim 3, wherein the set of data includes a series of bits that are each assigned a bit location, wherein the subset of data combined by the first read tree segment is selected by checking every other one bit location, wherein the subset of data combined by the second read tree segment is selected by checking every other two bit locations, wherein the subset of data combined by the third read tree segment is selected by checking every other four bit locations, and wherein the subset of data combined by the fourth read tree segment is selected by checking every other eight bit locations.

6. The error correction circuit of claim 5, wherein the set of data includes 8 bits and wherein the parity data includes 4 bits such that there are 12 bit locations.

7. An application package comprising:
an application die;
a known good die coupled to the application die, the known good die further comprising:
a memory configured to hold write data;
a write tree configured to receive the write data and to generate parity data therefrom; and
a read tree configured to receive read data from memory and configured to receive parity data from the parity memory;
wherein the read tree generates an output indicative of whether a failure occurred within the data memory.

8. The application package of claim 7, wherein the write memory tree includes a plurality of write tree segments, and wherein the read memory tree includes a plurality of read tree segments.

9. The application package of claim 8, wherein each of the write tree segments are arranged in first, second and third stages, each of the stages including at least one logic exclusive OR gate, and wherein each of the read tree segments are arranged in first, second and third stages, each of the stages including at least one logic exclusive OR gate.

10. The application package of claim 9, wherein the read data from memory is received in the first stage of each of the segments of the read tree, and wherein the parity data from the parity memory is received in the second stage of each of the segments of the read tree.

11. The application package of claim 10, wherein the write memory tree includes four write tree segments, and wherein the read memory tree includes four read tree segments.

12. The application package of claim 7, further including input and output buffers configured to transmit write data to the memory and to transmit read data from the memory, wherein the memory is configured to be closer in proximity to the input and output buffers than is the parity memory to the input and output buffers.

13. A memory device comprising:
a data memory configured to store write data having a plurality of bits;
means for receiving write data for generating parity data from the write data;
a parity memory configured to receive and hold the parity data; and
means for receiving read data from the data memory and parity data from the parity memory and for indicating whether a failure occurred within the write data during storing of the write data in data memory.

14. The memory device of claim 13, further including means coupled to the read tree for identifying the bit within the write data affected by the failure when a failure is indicated.

15. The memory device of claim 13, further including means coupled to the read tree for receiving the output from the read tree and for correcting the read data when an error is indicated.

16. The application package of claim 14, wherein the means for identifying the bit within the write data is a detector circuit coupled to the read tree and configured to receive the output from the read tree such that the detector corrects the read data when an error is indicated.

17. An error correction circuit comprising:
a data memory configured to receive and to store a set of data;
a write tree having a plurality of segments each configured to receive the set of data and each configured to generate a parity bit;
a parity memory coupled to the write tree configured to receive and store the parity bits; and
a read tree having a plurality of segments each configured to receive a subset of the set of data from the data memory and each configured to receive a parity bit from the parity memory;
wherein the read tree generates an indication of whether a failure occurred in the set of data stored in the data memory.

18. A method for detecting a failure within a memory device, the method comprising:
writing a set of data in a data memory;
writing the set of data to a write tree configured to receive the set of data;
generating parity bits with the write tree using the set of data;
storing the parity bits in a parity memory;
logically combining the set of data from the data memory and parity bits from the parity memory in a read tree; and
generating an indication of whether a failure occurred within the set of data written into the data memory.

19. The method of claim 18, wherein a first, a second, a third and a fourth write tree segment within the write tree are used to logically combine the set of data to produce the parity bits.

20. The method of claim 18, wherein a first, a second, a third and a fourth read tree segment within the read tree are used to logically combine a subset of the set of data from the data memory with one of the parity bits to determine whether a failure occurred in the set of data in the data memory.

21. The error correction circuit of claim 18, further including combining the subset of data with the read tree segments according to a modified Hamming code.

22. A method for fabricating an application package comprising:
providing an application die;
coupled a known good die to the application die;
writing a set of data in a data memory;
writing the set of data to a write tree configured to receive the set of data;
generating parity bits with the write tree using the set of data;
logically combining the set of data from the data memory with the parity bits; and
generating an indication of whether a failure occurred within the set of data written into the data memory.

23. The method of claim 22, further logically combining the set of data from the data memory with the parity bits using an exclusive logic OR operation.

24. An error correction method comprising:
storing a set of data in a data memory;
generating a parity bit in each segment of a write tree having a plurality of segments using the set of data;
storing the parity bits generated by the plurality of segments in the write tree;
combining a subset of the set of data from the data memory with a parity bit from the parity memory in each segment of a read tree having a plurality of segments;
generating an indication of whether a failure occurred in the set of data stored in the data memory from the combination of the of the set of data from the data memory with a parity bit.
